(19) United States
(12) Patent Application Publication
(10) Pub. No.: US 2012/0013487 A1
(43) Pub. Date: Jan. 19, 2012

(54) Revolving Control Device with a Displacement Sensor without Contact Points

(75) Inventor: Wei HSU, Chung Ho City (TW)

(73) Assignee: Weistech Technology Co., LTD., Chung Ho City (TW)

(21) Appl. No.: 12/879,024

(22) Filed: Sep. 10, 2010

(30) Foreign Application Priority Data
Jul. 13, 2010 (TW) 099123042

(51) Int. Cl. H03M 11/00

(52) U.S. Cl. 341/20

(57) ABSTRACT

The present invention discloses a revolving control device with a displacement sensor without contact points, which includes: a shell; a control stick configured in the shell and having a part protruding from the shell; a first circuit board configured on one end of the control stick; a displacement sensor configured in the shell, whereby detecting displacement of the control stick; a second circuit board embedded in the shell; a integrated circuit configured on the second circuit board, whereby detecting displacement of the shell; a plurality of transferring elements coupled between the first circuit board and the second circuit board; and wherein, the revolving control device can access control signals without contact points.

### CROSS-REFERENCE TO RELATED APPLICATION

This present application claims priority to TAIWAN Patent Application Serial Number 099123042, filed Jul. 13, 2010, which is herein incorporated by reference.

### TECHNICAL FIELD

The present invention generally relates to a revolving control device, especially to a revolving control device with a displacement sensor without contact points.

### DESCRIPTION OF THE RELATED ART

In current technical products, such as a mouse, a game pad, a presenter, or a cell phone, a micro joystick is introduced as a revolving control device. And comparing with control devices with buttons, which can generate signals with only one direction, the revolving control device is more convenient because it can revolve around 360 degrees to generate control signals with various directions. Therefore, the revolving control device becomes an indispensable element of computer pointing devices in place of the conventional pressing control device.

A conventional revolving control device includes a control stick and two VRs (variable resistor) used to detect horizontal and vertical displacement respectively. When the control stick revolves, the pointer connected to the VRs will swing in accordance with the angle the control stick revolves, thereby changing the resistance of the VRs. Therefore, any angle that the control stick revolves will correspond with a single resistance, thus, the location of the control stick can be determined by the VRs, contrarily, the resistance of VRs can be changed by revolving the control stick so as to generate a particular control signal, thereby implementing the function of a control device. Besides, an optical encoder can also be used to detect the displacement of the control stick, and generate signals of location, thus, it can be introduced to replace the VRs.

However, the pointer of the control stick may contact the VRs in the revolving control device with VRs, therefore, friction will exist in this kind of revolving control device, such that life of the revolving control device will be decreased. Furthermore, adjustment of VRs is required before using the revolving control devices every time, so as to regulate the initial control signal to be zero, whereby preventing error existing in the initial resistance. Besides, mechanical friction or varying impact will be generated because the pointer of the control stick scrubs the VRs in long time, thereby causing destructive abrasion on the surface and structure of VRs and further affecting the resistance of VRs, which will decrease accuracy and stability of control signals. Furthermore, because VR is a passive element, the resistance may be affected by factors of circumstance (such as temperature, humidity, etc), thereby decreasing the accuracy and stability of control signals. Aforementioned description points out the shortcomings of the revolving control device with VRs. Although replacing VRs with an optical encoder may overcome aforementioned shortcomings, there must be luminous elements and raster configured in the control device to detect the displacement or rotation of the control stick, thus, the cost will be inevitable to increase. Furthermore, there will be error of control signals if external light irradiate into the shell of the control device.

Therefore, there are still many shortcomings and difficulties in the conventional revolving control device.

### SUMMARY

To overcome aforementioned shortcomings and difficulties, the present invention discloses a revolving control device with a displacement sensor without contact points, which includes: a shell; a control stick configured in the shell and having a part protruding from the shell; a first circuit board configured on one end of the control stick; a displacement sensor configured in the shell, whereby detecting displacement of the control stick; a second circuit board embedded in the shell and welded with an integrated circuit for calculating displacement of the shell; a plurality of transferring elements coupled between the first circuit board and the second circuit board for transferring signals; and wherein, there are a plurality of pins embedded in the second circuit board to facilitate to transfer signals and power.

The present invention can be further understood by the following description of the preferred embodiment accompanying with the claims.

### BRIEF DESCRIPTION OF THE DRAWINGS

FIG. 1 shows the appearance of an embodiment of the present invention.

FIG. 2 shows the interior of the preferred embodiment of the present invention.

FIG. 3 shows a portion of another embodiment of the present invention.

FIG. 4 shows an embodiment of the control stick 100 of the present invention.

FIG. 5 shows the one operation status of the present invention.

FIG. 6 shows another operation status of the present invention.

FIG. 7 shows the appearance of an embodiment of the present invention.

### DETAILED DESCRIPTION

Some sample embodiments of the invention will now be described in greater detail. Nevertheless, it should be recognized that the present invention can be practiced in a wide range of other embodiments besides those explicitly described, and the scope of the present invention is expressly not limited expect as specified in the accompanying claims.

The present invention generally relates to a revolving control device, especially to a revolving control device with a displacement sensor without contact points, which uses a displacement sensor to detect displacement of the control stick, thereby overcoming aforementioned shortcomings of the conventional revolving control device effectively. Specifically, aforementioned displacement sensor is a gravity sensor.

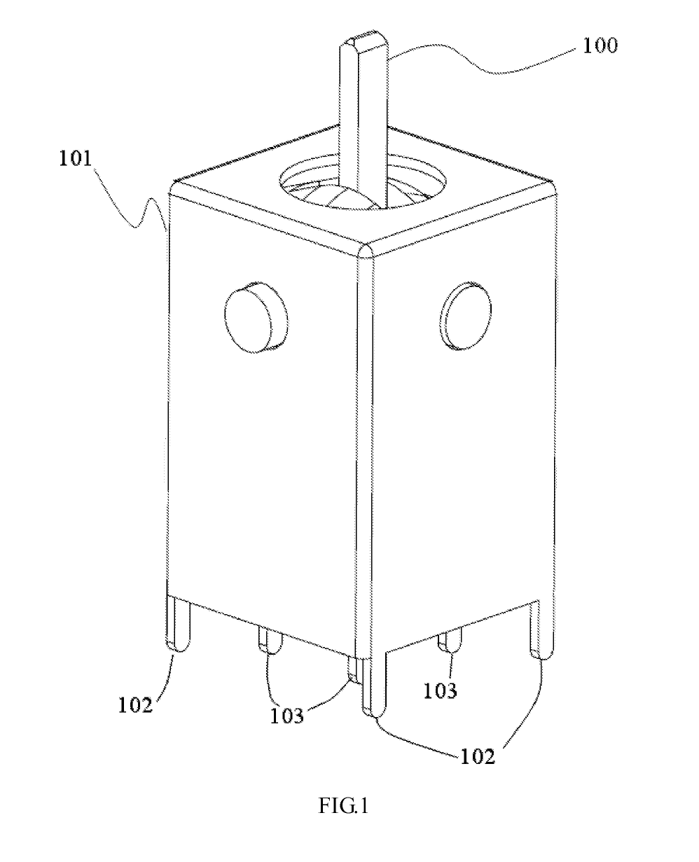

Referred to FIG. 1, which shows the appearance of an embodiment of the present invention, the revolving control device with a displacement sensor without contact points includes a control stick 100, a shell 101, four connecting sticks 102 and four pins 103, wherein the shell 101 has an opening to offer a part of the control stick 100 protruding from the opening, and the control stick 100 can be swung in any direction or revolved in any angle without exceeding the opening of the shell 101, whereby providing users can operate or use the revolving control device without being limited by directions or angles. And four connecting sticks 102 is configured at the endpoints on the lower surface of the shell 101 for connecting and being fixed to an external support (such as the shell of a joystick, a mouse, or a presenter), and pins 103 are introduced to transmit control signals of the revolving control device to an external processor (such as the processor of a joystick, a mouse or a presenter). It should be noted that locations and quantities of connecting sticks 102 and pins 103 can be changed by any person skilled in the art.

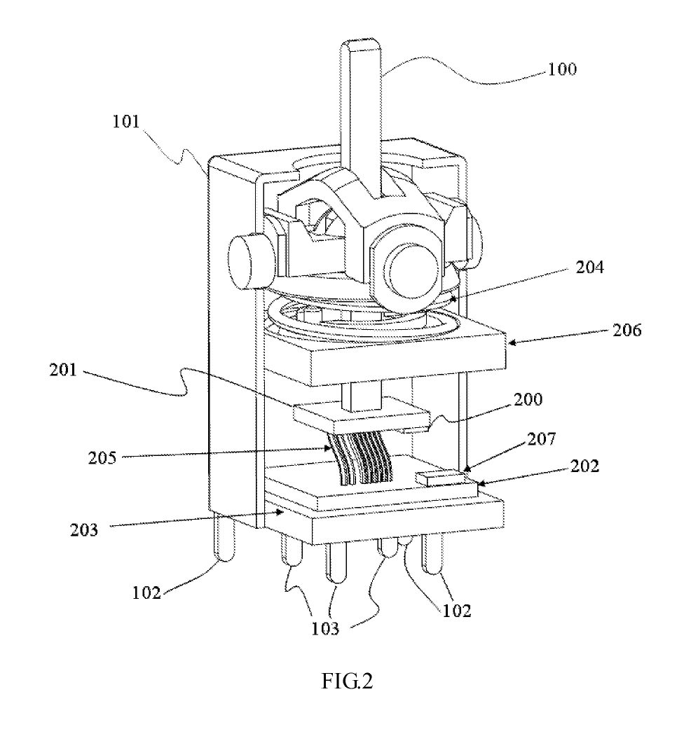

Referred to FIG. 2, which shows the interior of the preferred embodiment of the present invention, the revolving control device with a displacement sensor without contact points includes a control stick 100, a shell 101, four connecting sticks 102, four pins 103, a displacement sensor 200, a first circuit board 201, an integrated circuit 202, a second circuit board 203, an elastic element 204, a displacement sensor of the shell 207, and a plurality of transferring elements 205, wherein, a inner plate 206 is configured in the shell 101, and the elastic element 204 is configured between the control stick 100 and the inner plate 206 so as to keep the control stick 100 vertical when the control stick 100 is not forced. And the displacement sensor 200 is embedded on the first circuit board 201 which is embedded at the bottom of the control stick 100.

When the control stick 100 revolves or swings, location of the displacement sensor 200 will be moved subsequently, thereby detecting the displacement of the control stick 100 and generating control signals, and the control signals can be transferred to the integrated circuit 202 on the second circuit board 203 through the transferring elements 205 coupled between the first circuit board 201 and the second circuit board 203, and then can be transferred to an external processor (such as a processor of a joystick, a mouse, or a presenter) through the pins 103, wherein the second circuit board 203 is embedded on the bottom of the shell 101. However, in addition to detecting displacement of the control stick 100, the displacement sensor 200 may also detect displacement of the shell, thereby affecting the accuracy of control signals. Therefore, a displacement sensor of the shell 207 embedded on the second circuit board 203 is introduced to detect the displacement of the shell 101 in the present invention.

When the signal form the displacement sensor 200 is the same with the signal from the displacement sensor of the shell 207, it means that the controls stick 100 does not revolve or swing, so the signal reflects the displacement of the shell 101, namely, the signal reflects the displacement of the revolving control device. When the signal from the displacement sensor 200 is different from the signal from the displacement sensor of the shell 207, the difference between them reflects the signals that the control stick 100 revolves or swings, and the signal form the displacement sensor of the shell 207 can still reflect displacement of the revolving control device.

Furthermore, the signal reflecting the displacement of the shell 101 can be transferred to the integrated circuit 202 by the displacement sensor of the shell 207, and the integrated circuit 202 can eliminate the signal of the displacement sensor of the shell 207 from the signals of the displacement sensor 200, so as to alleviate inaccuracy raised by displacement of shell 101 effecting on the displacement sensor 200, thereby obtaining the signal which can truly reflect the displacement of the control stick 100. On the other hand, because the displacement sensor of the shell 207 can detect displacement of the shell 101, the displacement of the revolving control device can be detected, thus, users can also move the revolving control device directly to operate.

Therefore, in the present invention, control can be achieved by revolving or swinging the control stick 100 or moving the shell 101 either. Additionally, various control signals can be generated by revolving or swinging the control stick 100 or moving the shell 101 respectively, thereby implementing different kinds of control means. In the embodiment, the displacement sensor 200 is an analog gravity sensor, and in which three transferring cables are required to transfer signals reflecting the displacement in three dimensions respectively, thus, the transferring elements 205 comprise three transferring cables and two power cables to offer power to the displacement sensor 200.

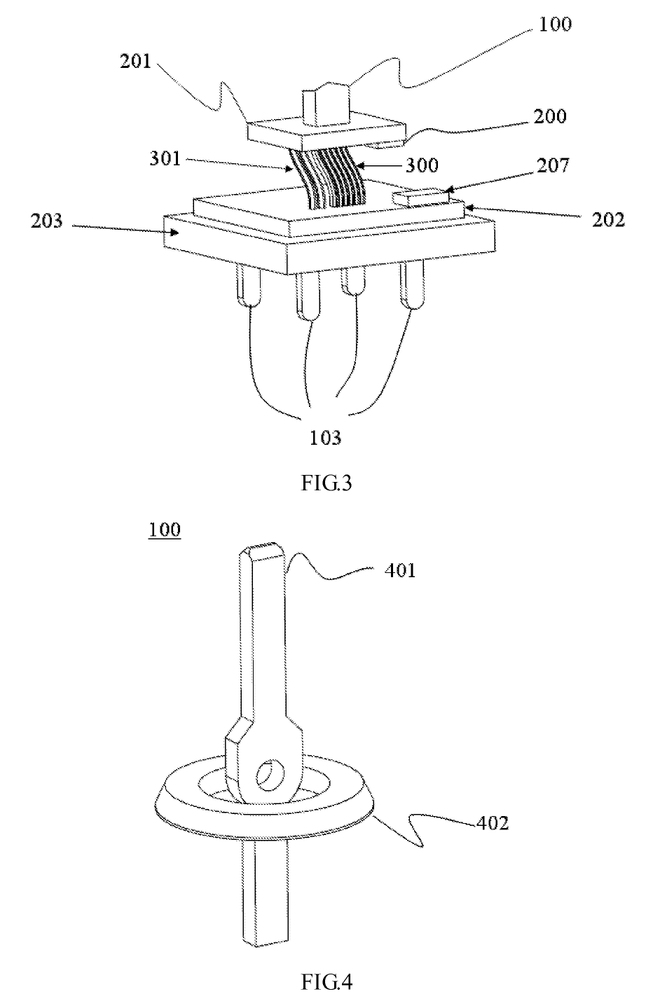

Referred to FIG. 3, which shows a portion of another embodiment of the present invention, the revolving control device with a displacement sensor without contact points includes a control stick 100, a displacement sensor 200, a first circuit board 201, a integrated circuit 202, a second circuit board 203, four pins 103, and a displacement sensor of the shell 207. This embodiment is similar to aforementioned embodiment disclosed in the FIG. 2, and difference is that the displacement sensor 200 of the embodiment is a digital gravity sensor, and in which a flexible flat cable 300 can be introduced to transfer digital signals, thus, the transferring elements 205 coupled between the first circuit board 201 and the second circuit board 203 comprise a flexible flat cable 300 and two power cables 301. Specifically, the flexible flat cable 300 can be a I2C bus or a SPI bus.

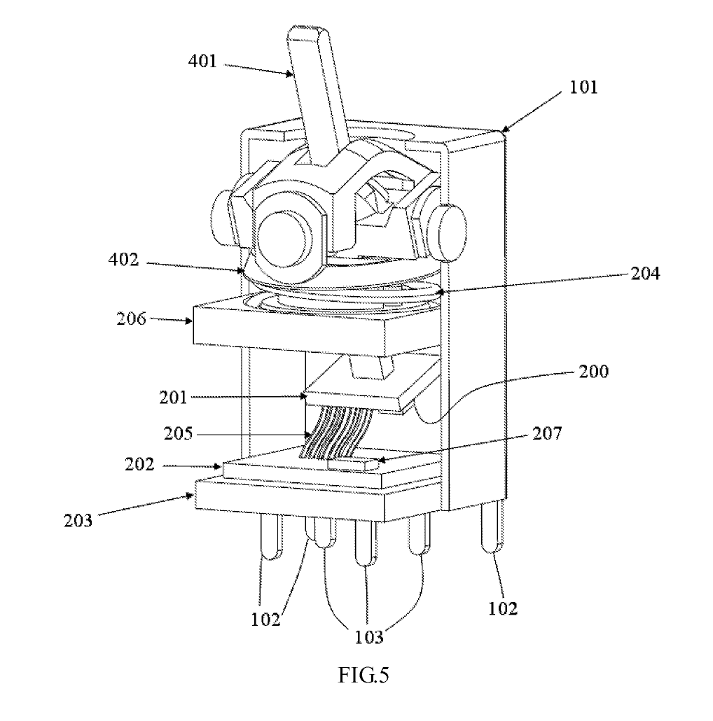

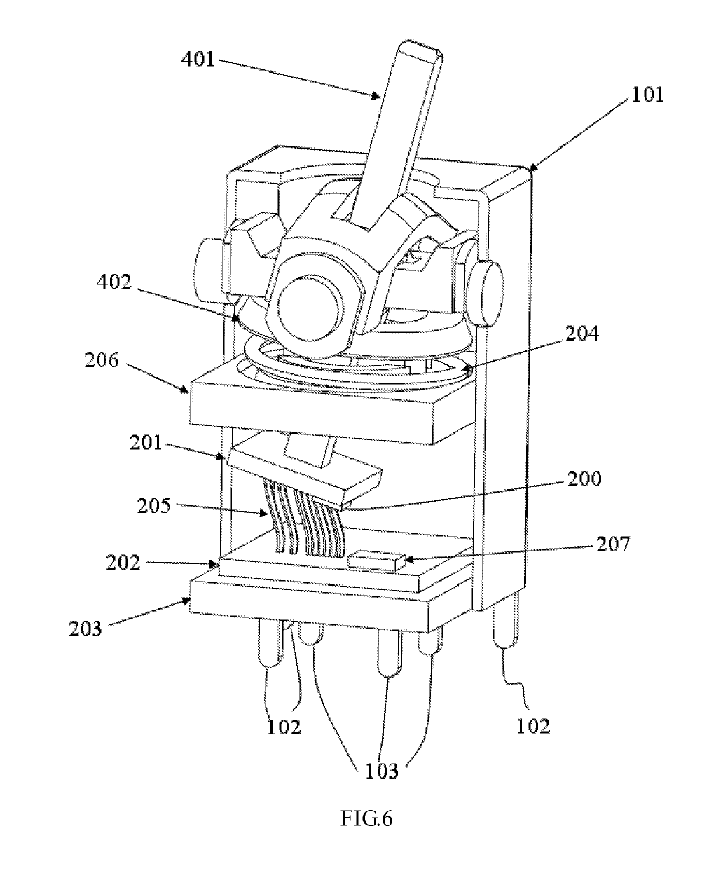

Referred to FIG. 4, which shows an embodiment of the control stick 100 of the present invention, the control stick 100 includes a vertical stick 401 and a horizontal plate 402, wherein the horizontal plate 402 is embedded on the vertical stick 401. Referred to FIG. 5 and FIG. 6, the control stick 100 is swung to one side in FIG. 5 and swung to another side in FIG. 6, wherein the horizontal plate 402 is introduced to press the elastic element 204. When a user swing or revolve the vertical stick 401, the horizontal plate 402 will swing or revolve subsequently, thereby deforming the elastic element 204. The specific operation means are depicted in FIG. 5 and FIG. 6. In FIG. 5, when a user turn the vertical stick 401 to front side, the horizontal plate 402 will incline to front side subsequently, thereby pressing the front side of the elastic element 204 and stretching the back side of the elastic element 204.

However, in FIG. 6, when the user turn the vertical stick 401 to right side, the horizontal plate 402 will incline to right side, thereby pressing the right side of the elastic element 204 and stretching the left side of the elastic element 204. And when the user stops forcing on the vertical stick 401, the elastic element 204 will recover to the initial state due to the inherent elasticity, thereby recovering the plate 402 back to horizontal and the stick 401 back to vertical. In some embodiments, the elastic element 204 may be a spring, high elastic rubber, or high elastic sponge.

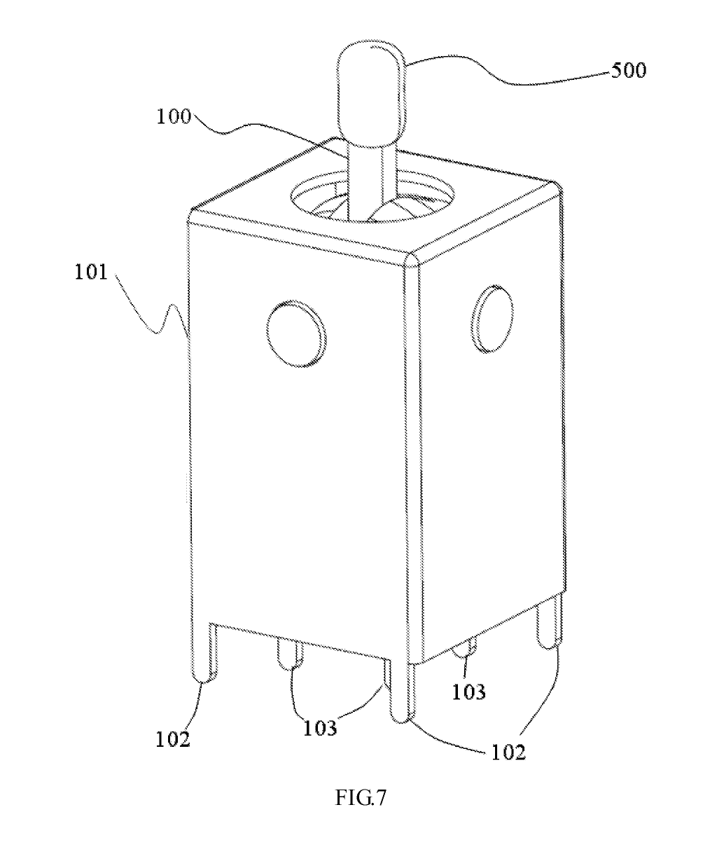

Referring to FIG. 7, which shows the appearance of the present invention, a revolving control device with a displacement sensor without contact points includes a control stick 100, a shell 101, four connecting sticks 102, four pins 103, and a sheath 500, wherein the top of the control stick 100 is covered by the sheath 500 which can be made by material with good sense of touch, such as rubber or leather. And the user can manipulate the control stick 100 by the sheath 500, thereby operating the revolving control device.

In some embodiments of the present invention, the displacement sensor of the shell 207 can be a capacitive accelerometer, an optical accelerometer, a digital gravity sensor, or a analog gravity sensor, etc. And the integrated circuit 202 may include a micro processor, a physical processor, or a DSP (digital signal processor).

One advantage of the present invention is that the control signal just depends on displacement because the displacement sensor is not affected by factors of circumstance such as temperature, pressure, humidity, or light, therefore, stability and accuracy will be increased.

Another advantage of the present invention is that the revolving control device can be operated easily by fingers (especially to a thumb) rather than conventional controller with the gravity sensor operated by the wrist or the arm, thereby alleviating pain raised by overusing the wrist or the arm.

The other advantage of the present invention is that the revolving control device can be sold alone instead of conventional joystick, such as game pad of PS3, XBOX360, or Wii, which can just be sold in a kit.

As will be understood by persons skilled in the art, the foregoing preferred embodiment of the present invention is illustrative of the present invention rather than limiting the present invention. Having described the invention in connection with a preferred embodiment, modification will now suggest itself to those skilled in the art. Thus, the invention is not to be limited to this embodiment, but rather the invention is intended to cover various modifications and similar arrangements included within the spirit and scope of the appended claims, the scope of which should be accorded the broadest interpretation so as to encompass all such modifications and similar structures. While the preferred embodiment of the invention has been illustrated and described, it will be appreciated that various changes can be made therein without departing from the spirit and scope of the invention.

What is claimed is:

1. A revolving control device with a displacement sensor without contact points, including:
a shell;
a control stick configured in said shell and having a part protruding from said shell;
a first circuit board configured on one end of said control stick;
a displacement sensor configured in said shell, whereby detecting displacement of said control stick;
a second circuit board embedded in said shell;
an integrated circuit configured on said second circuit board, whereby detecting displacement of said shell;
a plurality of transferring elements coupled between said first circuit board and said second circuit board; and
wherein, said revolving control device can obtain control signals without contact points.

2. The revolving control device according to claim 1, wherein said displacement sensor is embedded on said first circuit board.

3. The revolving control device according to claim 1, further comprises an elastic element configured adjacent said control stick to keep said control stick vertical when said control stick is not forced.

4. The revolving control device according to claim 3, wherein said elastic element is a spring.

5. The revolving control device according to claim 3, wherein said control stick comprises a vertical stick and a horizontal plate embedded at said vertical stick, and said horizontal plate is used to press said elastic element.

6. The revolving control device according to claim 5, further comprises an inner plate embedded in said shell to support said elastic element, and said inner plate has an inner opening to provide said vertical to pass through.

7. The revolving control device according to claim 6, wherein said shell has an outer opening to provide said vertical stick to pass through.

8. The revolving control device according to claim 1, further comprises a plurality of pins embedded in said second circuit board to transmit control signals to a external processor.

9. The revolving control device according to claim 1, wherein said displacement sensor is an analog gravity sensor.

10. The revolving control device according to claim 9, wherein said plurality of transferring elements comprise three transferring cables and two power cables to offer power to said displacement sensor.

11. The revolving control device according to claim 1, wherein said displacement sensor is a digital gravity sensor.

12. The revolving control device according to claim 11, wherein said plurality of transferring elements comprise a flexible flat cable for transmitting displacement in three dimension and two power cables to offer power to said displacement sensor.

13. The revolving control device according to claim 11, wherein said flexible flat cable comprises an I2C bus or a SPI bus.

14. The revolving control device according to claim 1, wherein said displacement sensor comprises a capacitive accelerometer, a optical accelerometer, or a gravity sensor.
